(19) United States
(12) Patent Application Publication
(10) Pub. No.: US 2015/0062805 A1
(43) Pub. Date: Mar. 5, 2015

(54) ELECTRONIC DEVICE

(71) Applicant: FUJITSU LIMITED, Kawasaki-shi (JP)

(72) Inventors: Kenji Katsumata, Odawara (JP); Shingo Yamaguchi, Kawasaki (JP); Masumi Suzuki, Kawasaki (JP); Satoshi Watanabe, Setagaya (JP)

(21) Appl. No.: 14/461,709

(22) Filed: Aug. 18, 2014

(30) Foreign Application Priority Data
Sep. 5, 2013 (JP) 2013-184160

(51) Int. Cl. G06F 1/20; H05K 7/20; H05K 5/02

(52) U.S. Cl. CPC G06F 1/20; H05K 5/0213; H05K 7/20145
USPC 361/679.49

(57) ABSTRACT

An electronic device includes: a fan; a housing configured to houses the fan, the housing including a vent hole configured to introduce outside air, a first air outlet configured to open to a blowing path from the fan, and a second air outlet configured to open at a different position with respect to the blowing path; and an opening and closing member configured to open and close the first air outlet.

### CROSS-REFERENCE TO RELATED APPLICATION

This application is based upon and claims the benefit of priority of the prior Japanese Patent Application No. 2013-184160, filed on Sep. 5, 2013, the entire contents of which are incorporated herein by reference.

### FIELD

The embodiments discussed herein are related to an electronic device.

### BACKGROUND

Hitherto, an electronic device having a housing that includes a hole and in which water that has been produced inside a device body is discharged to the outside of the device body through the hole is known.

In such an electronic device, when a fan is provided to reduce a temperature of a heat-generating electronic component, there may be cases in which water disadvantageously spouts out from the hole due to air blown by the fan.

The following is a reference document.
[Document 1] Japanese Laid-open Patent Publication No. 08-203365.

### SUMMARY

According to an aspect of the invention, an electronic device includes: a fan; a housing configured to houses the fan, the housing including a vent hole configured to introduce outside air, a first air outlet configured to open to a blowing path from the fan, and a second air outlet configured to open at a different position with respect to the blowing path; and an opening and closing member configured to open and close the first air outlet.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a bottom view of a tablet terminal according to a first embodiment;

FIG. 2 is a longitudinal section of the tablet terminal according to the first embodiment taken along the line A-A of FIG. 1 illustrating a state in which a first air outlet is open and a second air outlet is closed;

FIG. 3 is an enlarged view of a main portion schematically illustrating a left lateral surface of the tablet terminal according to the first embodiment;

FIG. 4 is a longitudinal section of the tablet terminal according to the first embodiment taken along the line A-A of FIG. 1 illustrating a state in which the first air outlet is closed and the second air outlet is open;

FIG. 5 is a longitudinal section of a tablet terminal according to a second embodiment illustrating a state in which the first air outlet is open and the second air outlet is closed;

FIG. 6 is a longitudinal section of the tablet terminal according to the second embodiment illustrating a state in which the first air outlet is closed and a second air outlet is open;

FIG. 7 is a longitudinal section of a tablet terminal according to a third embodiment illustrating a state in which the first air outlet is open and the second air outlet is closed; and

FIG. 8 is a longitudinal section of the tablet terminal according to the third embodiment illustrating a state in which the first air outlet is closed and the second air outlet is open.

### DESCRIPTION OF EMBODIMENTS

### First Embodiment

A first embodiment of the embodiments discussed herein will be described.

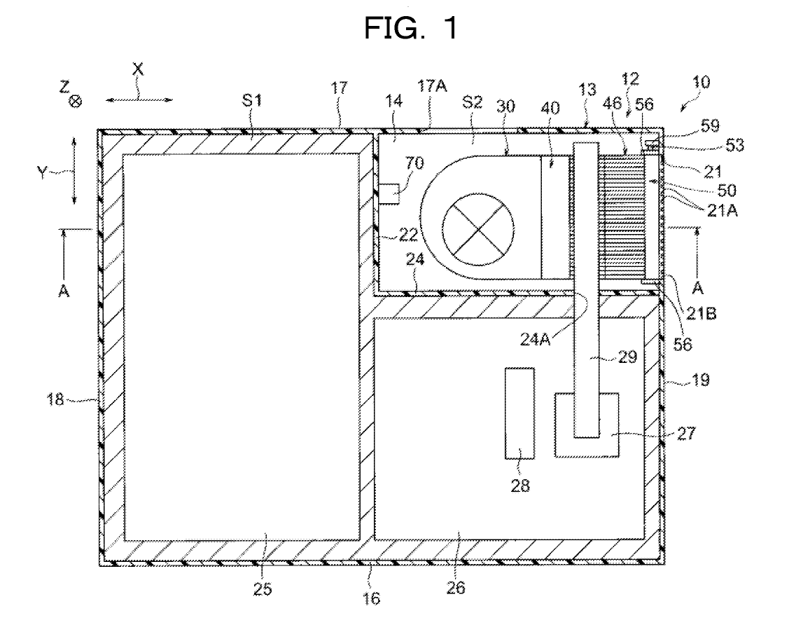

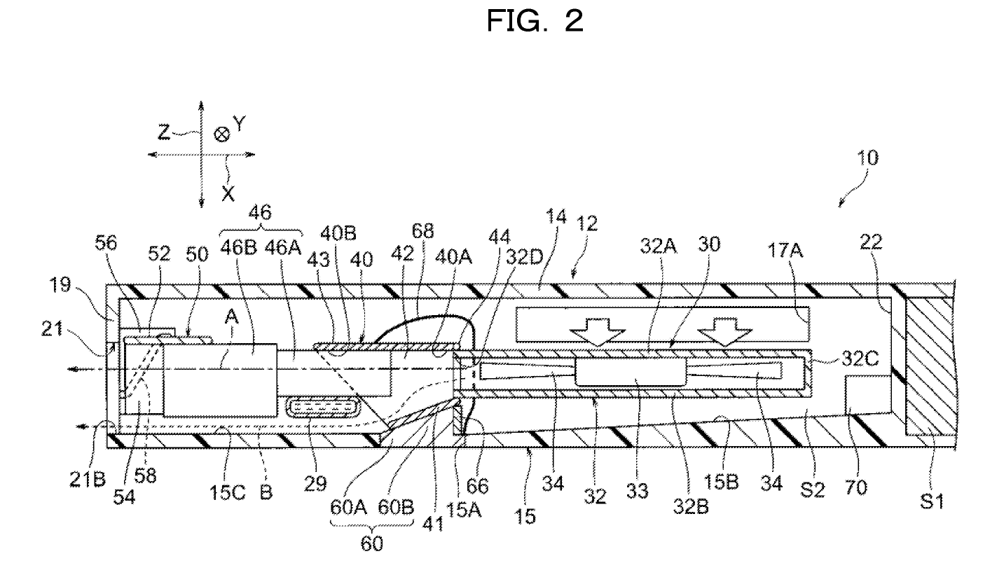

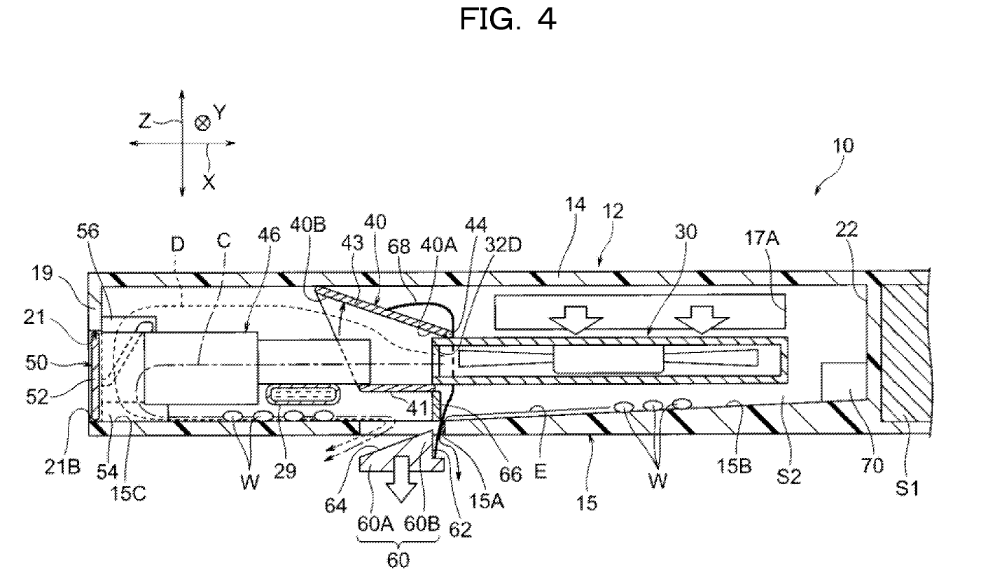

FIG. 1 illustrates a bottom view illustrating an internal structure of a tablet terminal 10 serving as an example of an electronic device. Note that, in each of the drawings, the width direction of the tablet terminal 10 is indicated by an arrow X, the depth direction by an arrow Y, and the thickness direction (the up-down direction) by an arrow Z. Furthermore, in the following description, the arrangement of each component of the tablet terminal 10 will be described using the terms right side (the left side of FIG. 1), left side (the right side of FIG. 1), front side, rear side, upper side, and lower side. Additionally, the brake line A-A that extends in the X direction across a portion of the tablet terminal 10 on the far side with respect to the middle of the tablet terminal 10 in the Y direction are illustrated in FIG. 1. Sections taken along the brake line A-A are illustrated in FIGS. 2 and 4.

The tablet terminal 10 includes a housing 12 that forms a device body, a fan unit 30 serving as an example of a fan that is housed in the housing 12, and a first duct member 40 serving as an example of a guide member. The tablet terminal 10 further includes radiation fins 46 serving as an example of a heat conductor, a second duct member 50 serving as an example of an opening and closing member, and a cover member 60 (see FIG. 2).

Furthermore, the tablet terminal 10 includes a humidity sensor 70 serving as an example of a humidity detecting unit. Additionally, in the tablet terminal 10, a touch panel (not shown) for performing input operations and for displaying information is provided on the upper side of the housing 12.

Housing

The housing 12 includes sidewalls 13 that are, for example, formed of resin and that are erected in the Z direction so as to be arranged in a rectangular shape in plan view, an upper wall 14 that covers the upper side of the sidewalls 13, and a bottom wall 15 (see FIG. 2) that covers the lower side of the sidewalls 13. The sidewalls 13 include a front wall 16 disposed on the front side, a rear wall 17 disposed on the rear side, a right wall 18 disposed on the right side, and a left wall 19 disposed on the left side.

Furthermore, a partition wall 22 and a partition wall 24 are provided inside the housing 12. The partition wall 22 stands erect on the bottom wall 15 (see FIG. 2) and extends from the middle of the rear wall 17 in the X direction and from the inner surface of the rear wall 17 to the middle portion of the housing 12. The partition wall 24 stands erect on the bottom wall 15 (see FIG. 2) and extends from the inner surface of the left wall 19 and from the middle of the left wall 19 in the Y direction to the middle portion of the housing 12. Moreover, one end of the partition wall 22 in the Y direction and one end of the partition wall 24 in the X direction are connected to each other.

The inside of the housing 12 is partitioned by the partition wall 22 and the partition wall 24 such that the inside of the housing 12 is divided into a waterproof area S1 and a non-waterproof area S2 in plan view. In FIG. 1, other than the area where the battery 25 and the circuit substrate 26 that are described later are arranged, the waterproof area S1 is indicated with oblique lines.

Waterproof Area

The waterproof area S1 is surrounded by the bottom wall 15 (see FIG. 2), the upper wall 14 (see FIG. 2), the front wall 16, the right wall 18, the rear wall 17, the partition wall 22, the partition wall 24, and the left wall 19. A sealing material (not shown) is attached to the periphery of the waterproof area S1 such that infiltration of liquid into the waterproof area S1 from the outside of the housing 12 is restrained. Note that, in the present embodiment, while water is described as an example of a liquid, other liquids may be applied in a similar manner. Furthermore, the waterproof area S1 is provided with a battery 25 that supplies electric power to each component in the tablet terminal 10 and with the circuit substrate 26 serving as an example of a controller that carries out operation control of each component of the tablet terminal 10.

Circuit Substrate

A variety of electronic components are mounted on the circuit substrate 26. The variety of electronic components include, for example, a central processing unit (CPU) 27 that is in charge of the overall control of the tablet terminal 10, a chipset (not shown) that controls data transmission and the like of the CPU 27 and the like, and a memory 28 that stores data. Furthermore, the circuit substrate 26 operates on electric power supplied from the battery 25. Furthermore, an electric signal associated with the operation of the touch panel (not shown) is input to the circuit substrate 26 and an electric signal associated with the display information sent to the touch panel is output from the circuit substrate 26.

A moving image program serving as an example of a program that carries out control that increases the temperature of the CPU 27, the moving image program displaying moving images on the touch panel, is stored in the memory 28. Execution of the moving image program by the CPU 27 imposes an operational load on the CPU 27; accordingly, the temperature of the CPU 27 is increased compared with the temperature of the CPU 27 when the tablet terminal 10 is booted up.

In other words, the circuit substrate 26 operates the CPU 27 when water is to be discharged from the housing 12 (for example, when the circuit substrate 26 receives, from the humidity sensor 70 described later, a command to discharge water) and carries out control of increasing the temperature of the CPU 27 to a temperature higher than the temperature when water is not discharged from the housing 12. Note that the program for carrying out control of increasing the temperature of the CPU 27 is not limited to the moving image program and a benchmark test program (load program) may be used.

The CPU 27 is a component that generates heat when executing signal processing. In order to avert malfunction and the like due to generation of heat, the CPU 27 is preferably cooled during the operation of the tablet terminal 10. Accordingly, one end of a heat pipe 29 serving as an example of a heat conduction member is in contact with the CPU 27.

Heat Pipe

The heat pipe 29 is inserted through a through hole 24A that is formed in the partition wall 24 and is disposed across the waterproof area S1 and the non-waterproof area S2. Furthermore, the other end of the heat pipe 29 is in contact with the undersurface (lower portion) of the first radiation portion 46A (see FIG. 2) of the radiation fins 46 described later in the non-waterproof area S2. Note that the gap between the heat pipe 29 and the through hole 24A is filled with a sealing material and a gasket (both not shown).

Furthermore, the heat pipe 29 is a hermetic container having a capillary structure with a working fluid filled therein. Moreover, in the heat pipe 29, the working fluid heated by the radiation of the CPU 27 is evaporated and the vapor is condensed on the low-temperature side where the radiation fins 46 are provided; accordingly, the heat of the CPU 27 is transmitted to the radiation fins 46.

Non-waterproof Area

The non-waterproof area S2 is surrounded by the bottom wall 15 (see FIG. 2), the upper wall 14 (see FIG. 2), the rear wall 17, the left wall 19, the partition wall 22, and the partition wall 24. A vent hole 17A that penetrates the rear wall 17 in the Y direction is formed in the rear wall 17 of the non-waterproof area S2 at a portion near the middle of the rear wall 17 in the X direction. The vent hole 17A is, for example, formed in a rectangular shape whose longitudinal direction extends in the X direction. The vent hole 17A has a size large enough to allow the outside air and water to flow into the non-waterproof area S2 from the outside of the housing 12.

The left wall 19 is disposed so as to face the blowing direction (the X direction) of a blowing path A (indicated by an arrow A with a dot and dash line in FIG. 2) of the fan unit 30 described later. Moreover, a first air outlet 21 that penetrates the left wall 19 of the non-waterproof area S2 in the X direction is formed in the left wall 19 of the non-waterproof area S2. In other words, the first air outlet 21 is open to the blowing path A that extends from the fan unit 30.

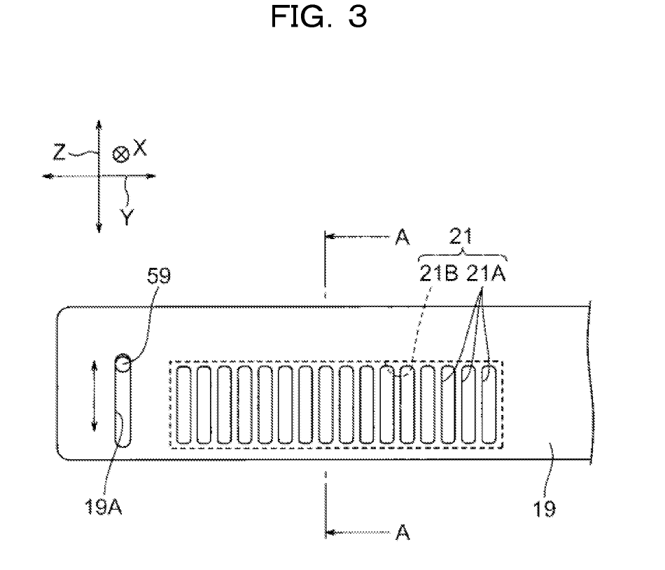

The first air outlet 21 has a size that is large enough to allow ventilation to be carried out from the non-waterproof area S2 to the outside of the housing 12. Furthermore, the first air outlet 21 includes, for example, a plurality of long holes 21A (see FIG. 3) that are aligned in the Y direction and that are each elongated in the Z direction and a single through hole 21B that is formed inside the plurality of long holes 21A in the X direction and that is in communication with the plurality of long holes 21A. Moreover, by displacing a top plate 52 of the second duct member 50 described later (see FIG. 2) such that the top plate 52 is accommodated in the through hole 21B, the plurality of long holes 21A are closed; accordingly, ventilation in the first air outlet 21 from the non-waterproof area S2 to the outside of the housing 12 is cut off.

As illustrated in FIG. 2, the bottom wall 15 is disposed along the XY plane so that the bottom wall 15 faces a direction (as an example, the Z direction) that is different to the blowing direction (the X direction) of the fan unit 30. Moreover, a second air outlet 15A that penetrates the bottom wall 15 of the non-waterproof area S2 in the Z direction is formed in the bottom wall 15 of the non-waterproof area S2.

The second air outlet 15A is, for example, a through hole that has a rectangular shape in plan view and that is disposed alongside the first duct member 40 in the Z direction. In other words, the second air outlet 15A is open at a different position with respect to the blowing path A. Furthermore, the second air outlet 15A is closed by attaching the cover member 60 described later thereto such that ventilation and discharge of water from the non-waterproof area S2 to the outside of the housing 12 are cut off.

Note that, in the upper surface of the bottom wall 15, for example, the portion from the lower portion of the partition wall 22 to the second air outlet 15A is a downward inclined surface 15B. Furthermore, in the upper surface of the bottom wall 15, for example, the portion from the second air outlet 15A to the lower portion of the left wall 19 is a flat surface 15C extending along the XY plane.

Cover Member

As illustrated in FIG. 4, when seen from the Y direction, the cover member 60 has a sectional shape formed of a rectangular bottom portion 60A and a support portion 60B, which is disposed on the upper side of the bottom portion 60A and that has a right angled triangle shape, integrated together. One end of a wire member 68 serving as an example of a connection member is connected to one end of the bottom portion 60A in the X direction. Furthermore, the support portion 60B includes a guided surface 62 extending erect along the YZ plane and an inclined surface 64 that is inclined downwards from the upper end of the guided surface 62 towards the other end of the bottom portion 60A in the X direction.

The cover member 60 closes the second air outlet 15A when the second duct member 50 described later is in an open position and opens the second air outlet 15A when the second duct member 50 is in a closed position. In other words, the cover member 60 opens the second air outlet 15A by being detached from the second air outlet 15A and closes the second air outlet 15A by being attached to the second air outlet 15A. Furthermore, upon opening and closing of the cover member 60, the wire member 68 opens and closes the first duct member 40.

A plate-shaped guide wall 66 that stands erect along the YZ plane is provided on the upper side of the second air outlet 15A. The cover member 60 is guided into the second air outlet 15A as a result of displacing the cover member 60 towards the upper side while the guided surface 62 is in contact with one of the lateral surfaces of the guide wall 66. Note that by having the undersurface of the guide wall 66 come into contact with the one end of the bottom portion 60A in the X direction, the peripheral edge of the bottom portion 60A is fitted to the second air outlet 15A and the cover member 60 is restricted from entering into the housing 12. Furthermore, in a state in which the cover member 60 is fitted to the second air outlet 15A, an undersurface of a bottom plate 41 of the first duct member 40 is in contact with the inclined surface 64 such that the first duct member 40 is supported by the cover member 60.

As illustrated in FIG. 1, the fan unit 30, the first duct member 40, the radiation fins 46, the second duct member 50, and the humidity sensor 70 are housed in the non-waterproof area S2.

Fan Unit

As illustrated in FIG. 2, the fan unit 30 is, for example, a sirocco fan and includes a fan cover 32 serving as a body. A rotating shaft 33 whose axial direction extends in the Z direction and that is rotationally driven by a motor (not shown) and a plurality of moving blades 34 formed integrally on the outer periphery of the rotating shaft 33 are provided inside the fan cover 32. Furthermore, rotation of the rotating shaft 33 and the plurality of moving blades 34 in the fan unit 30 results in air being blown along the blowing path A.

The fan cover 32 includes a top plate 32A disposed on the upper side in the Z direction, a bottom plate 32B disposed on the lower side in the Z direction, and side plates 32C. The top plate 32A is disposed so as to be spaced apart from and parallel to the upper wall 14. Furthermore, an inlet port (not shown) that penetrates the top plate 32A in the Z direction and that takes in air is formed in the top plate 32A. The bottom plate 32B and the bottom wall 15 are arranged so as to be spaced apart from each other. Furthermore, the bottom plate 32B is fixed above the bottom wall 15 with brackets (not shown) that are provided on the front side and the rear side of the bottom plate 32B in the Y direction.

Furthermore, a blowing port 32D that penetrates the fan cover 32 in the X direction and that faces the radiation fins 46 is formed on one end side of the fan cover 32 in the X direction. Accordingly, in the housing 12, air blown by the fan unit 30 is blown onto the radiation fins 46 such that the CPU 27 (see FIG. 1) is indirectly cooled through the heat pipe 29.

First Duct Member

As illustrated in FIG. 2, the first duct member 40 is provided between the fan unit 30 and the radiation fins 46. Furthermore, the first duct member 40 includes the bottom plate 41, two sidewalls 42 each standing erect in the Z direction on the front side and the rear side of the bottom plate 41 in the Y direction spaced apart from each other, and a top plate 43 that connects the upper sides of two sidewalls 42. In other words, the first duct member 40 is formed in a tube shape that extends in the X direction.

Furthermore, in the first duct member 40, the area of an opening 40B that is on the side (the outflow side of the air) that is adjacent to the radiation fins 46 is larger than the opening area of an opening 40A that is on the side (the inflow side of the air) that is adjacent to the fan unit 30. Additionally, in the first duct member 40, the size of the opening on the side that is adjacent to the radiation fins 46 is larger than the size of the external shape of the radiation fins 46.

One end of the bottom plate 41 in the X direction is disposed between the guide wall 66 and the bottom plate 32B of the fan cover 32. Furthermore, the other end of the bottom plate 41 in the X direction extends to the vicinity of the lower side of the first radiation portion 46A of the radiation fins 46 described later. Moreover, while the cover member 60 is attached to the second air outlet 15A, the bottom plate 41 is disposed in an inclined manner and is supported by the cover member 60. Accordingly, when water is not discharged from the housing 12, the first duct member 40 is supported by the cover member 60.

One end of the top plate 43 in the X direction is disposed on the upper side of the top plate 32A of the fan cover 32, and the other end of the top plate 43 in the X direction is disposed on the upper side of the first radiation portion 46A of the radiation fins 46. In other words, for example, a portion of the first radiation portion 46A of the radiation fins 46 is accommodated inside the first duct member 40.

Furthermore, pins 44, whose axial direction extends in the Y direction, are provided in the one end of the top plate 43 in the X direction, each on the front side and rear side of the top plate 43 in the Y direction. The pins 44 are inserted into guide grooves (not shown) that are formed in a pair of side plates such that sliding and rotation of the pins 44 in the X direction along the guide grooves may be performed. In other words, the other end of the first duct member 40 in the X direction may be moved up and down in an arc about the pins 44 at the one end of the first duct member 40 in the X direction.

Accordingly, the first duct member 40 covers a portion from the blowing port 32D of the fan unit 30 to the first radiation portion 46A of the radiation fins 46. Accordingly, air blown out from the blowing port 32D is guided to the radiation fins 46 by the first duct member 40.

Furthermore, the first duct member 40 is disposed so as to be aligned with the second air outlet 15A in the Z direction. Moreover, in the first duct member 40, the other end of the wire member 68 is connected to the top plate 43. With the above, when the cover member 60 is pulled out from the second air outlet 15A towards the lower side in the Z direction, the top plate 43 is pulled by the wire member 68 and the other end of the first duct member 40 in the X direction is lifted towards the upper side. In other words, when the second air outlet 15A is open, the first duct member 40 guides the air blown out from the fan unit 30 to the radiation fins 46 and the upper portion of the housing 12.

Radiation Fins

As illustrated in FIG. 2, the radiation fins 46 are provided between the fan unit 30 and the first air outlet 21. Furthermore, the radiation fins 46 include the first radiation portion 46A and a second radiation portion 46B that has a larger radiation area than that of the first radiation portion 46A. In the first radiation portion 46A and the second radiation portion 46B, a plurality of metal plates is aligned in the Y direction spaced apart from one another. Furthermore, the radiation fins 46 are fixed above the bottom wall 15 with brackets (not shown) provided on the front side and the rear side of the radiation fins 46 in the Y direction. Additionally, the radiation fins 46 release heat of the CPU 27 (see FIG. 1) through the heat pipe 29.

Second Duct Member

As illustrated in FIG. 2, the second duct member 50 is provided between the radiation fins 46 and the left wall 19. Furthermore, the second duct member 50 includes the top plate 52 and two sidewalls 54 disposed on the front side and the rear side of the top plate 52 in the Y direction spaced apart from each other. In other words, the second duct member 50 is formed so that a section viewed from the X direction has a C-shape. The external shape of the top plate 52 has a size that fits in the through hole 21B of the first air outlet 21. Furthermore, pins 53 (see FIG. 1) that project in the Y direction are provided at the two end surfaces of the top plate 52 in the Y direction.

Two plates 56 having the two sidewalls 54 of the second duct member 50 in between in the Y direction are provided in the housing 12 between the radiation fins 46 and the left wall 19. Guide grooves 58 are formed in the two plates 56. Furthermore, the pins 53 of the second duct member 50 (see FIG. 1) are inserted into the guide grooves 58. The pins 53 have an outer diameter that is slightly smaller than the width of the guide grooves 58 and are guided while being in contact with the guide grooves 58. Furthermore, one end of a columnar lever member 59 (see FIG. 1) is connected to one of the pins 53.

As illustrated in FIG. 3, a long hole 19A that is long in the Z direction is formed beside the first air outlet 21 in the left wall 19. Moreover, the lever member 59 passes through the long hole 19A and projects to the outside of the left wall 19. Accordingly, when the lever member 59 is operated towards the upper side in the Z direction, the second duct member 50 (see FIG. 2) moves to the open position, and when the lever member 59 is operated towards the lower side in the Z direction, the second duct member 50 moves to the closed position. In other words, with the operation of the lever member 59, the second duct member 50 may open and close the first air outlet 21.

As illustrated in FIG. 2, the open position of the second duct member 50 is a position in which one end of the top plate 52 is disposed on the upper side of the second radiation portion 46B, in which the other end of the top plate 52 covers a portion between the radiation fins 46 and the left wall 19, and in which the first air outlet 21 is open.

As illustrated in FIG. 4, the closed position of the second duct member 50 is a position in which the top plate 52 is fitted to the first air outlet 21 (the through hole 21B), in which the portion between the radiation fins 46 and the left wall 19 is open, and in which the first air outlet 21 is closed.

Humidity Sensor

As illustrated in FIG. 2, the humidity sensor 70 is fixed on the bottom wall 15 at a portion adjacent to the partition wall 22. Furthermore, the humidity sensor 70 is, for example, an electric humidity sensor that detects the humidity inside the housing 12 by detecting the change in permittivity that changes in accordance with the change in the amount of water contained in a polymeric membrane. Humidity data measured by the humidity sensor 70 is sent to the CPU 27 (see FIG. 1).

In the circuit substrate 26 illustrated in FIG. 1, the CPU 27 compares an upper limit of the humidity data that is stored in the memory 28 and the humidity data that has been detected by the humidity sensor 70 with each other. Then, when the humidity data detected by the humidity sensor 70 exceeds the upper limit (preset humidity), the CPU 27 determines that water has infiltrated into the non-waterproof area S2 or that there is excessive water in the non-waterproof area S2, and the moving image program described above is executed. In other words, the humidity data that has exceeded the preset humidity serves as a water discharge command. Note that a warning that the humidity data has exceeded the upper limit and a message that the moving image program is being executed are displayed on the touch panel described above (not shown), for example.

Functions and effects of the first embodiment will be described next.

During Normal Operation

As illustrated in FIG. 2, during normal operation of the tablet terminal 10 (when water W is not discharged from the housing 12), the first air outlet 21 is open, and the second air outlet 15A is closed by the cover member 60. In other words, the second air outlet 15A, being closed by the cover member 60, may suppress the blown air from leaking therefrom. Furthermore, since the first duct member 40 is supported by the cover member 60, the position of the first duct member 40 may be stabilized.

Next, when the fan unit 30 starts operating, air is blown out from the blowing port 32D. At this time, in the first duct member 40, the top plate 43 covers the portion from the fan unit 30 to the radiation fins 46, and the bottom plate 41 is disposed in an inclined manner. Accordingly, a portion of the air blown out from the fan unit 30 flows towards the radiation fins 46 along the blowing path A and the remaining portion flows towards a portion below the radiation fins 46.

The portion of the air blown out from the fan unit 30 flows through the radiation fins 46 and reduces the temperature of the radiation fins 46. At this time, since the top plate 52 of the second duct member 50 covers the portion from the radiation fins 46 to the left wall 19, as illustrated by the arrow A, the air that has flowed through the radiation fins 46 flows towards the first air outlet 21, passes through the first air outlet 21, and flows to the outside of the housing 12.

Meanwhile, as illustrated by an arrow B (a broken line), the remaining air blown out from the fan unit 30 flows towards the first air outlet 21 between the radiation fins 46 and the heat pipe 29, and the bottom wall 15 (the lower portion of the housing 12), passes through the first air outlet 21, and flows to the outside of the housing 12. Note that during normal operation, the humidity inside the non-waterproof area S2 detected by the humidity sensor 70 is lower than the preset humidity.

During Discharge Operation

When water is spilled on the tablet terminal 10 or when the tablet terminal 10 is dropped into a pool of water, for example, and water W infiltrates into the non-waterproof area S2, the user slides the lever member 59 illustrated in FIG. 3 towards the lower side with his/her finger. With the above, as illustrated in FIG. 4, the second duct member 50 rotates 90° and moves to the closed position and the top plate 52 closes the first air outlet 21. Note that a discharge operation period refers to a period when water W that has infiltrated into the housing 12 is discharged to the outside of the housing 12.

Furthermore, the user pulls the cover member 60 towards the lower side in the Z direction and detaches the cover member 60 from the bottom wall 15. With the above, the second air outlet 15A becomes open and the wire member 68 is pulled, and the end portion of the first duct member 40 is moved towards the upper side. In other words, the user may open the second air outlet 15A and move the first duct member 40 with a single operation, that is, by detaching the cover member 60; accordingly, the direction of air blown out from the fan unit 30 may be changed with a simple operation. Then, a gap allowing ventilation is formed between the top plate 43 and the radiation fins 46 and the bottom plate 41 is disposed between the radiation fins 46 and the fan unit 30.

Note that, in the tablet terminal 10, since the first duct member 40 is disposed so as to be aligned with the second air outlet 15A in the Z direction, compared with the case in which the first duct member 40 is not disposed so as to be aligned with the second air outlet 15A, the length of the wire member 68 may be short.

As illustrated by an arrow C (a dot and dash line), at this time, the air that has been guided by the first duct member 40 to flow from the fan unit 30 to the radiation fins 46 passes through the radiation fins 46 and flows towards the first air outlet 21; however, because the first air outlet 21 is closed, the air flows towards the lower side along the top plate 52. Furthermore, the blown air flows between the bottom wall 15 and the radiation fins 46, passes through the second air outlet 15A, and flows to the outside of the housing 12. Accordingly, the water W that has accumulated on the flat surface 15C of the bottom wall 15 is swept by the blown air, passes through the second air outlet 15A, and is discharged to the outside of the housing 12.

Furthermore, as illustrated by an arrow D (a broken line), the air that has been guided by the first duct member 40 to flow from the fan unit 30 along the top plate 43 flows between the radiation fins 46 and the upper wall 14, and flows to the lower side along the left wall 19 and the top plate 52. Moreover, the blown air flows between the bottom wall 15 and the radiation fins 46, passes through the second air outlet 15A, and flows to the outside of the housing 12. With the above, in the tablet terminal 10, water (not shown) adhered to the undersurface of the upper wall 14 (the upper portion of the housing 12) is swept by the blown air; accordingly, discharge of water W from the second air outlet 15A may be facilitated.

As above, in the tablet terminal 10, since the first air outlet 21 that is positioned in the blowing direction of the fan unit 30 is closed by the second duct member 50 during the discharge operation, it will be possible to suppress water W from spouting out from the first air outlet 21 due to the air blown out from the fan unit 30. Furthermore, in the tablet terminal 10, discharge of water W from portions of the housing 12 unintended by the user may be restricted since the water W is discharged from the second air outlet 15A when the user detaches the cover member 60. Note that even if the user changes (tilts) the position of the tablet terminal 10, discharge of water W from portions unintended by the user may be restricted since the water W is discharged from the second air outlet 15A.

Furthermore, in the tablet terminal 10, the CPU 27 (see FIG. 1) executes the moving image program when water W infiltrates into the non-waterproof area S2 and when the humidity sensor 70 detects a humidity that is equivalent to or higher than the preset humidity. Accordingly, operational load is imposed on the CPU 27 and the temperature of the CPU 27 is increased compared with the temperature of the CPU 27 when the tablet terminal 10 is booted up. Then, the heat of the CPU 27 is transmitted to the radiation fins 46 through the heat pipe 29 and the temperature of the radiation fins 46 increases.

Subsequently, with the increase in temperature of the radiation fins 46, the temperature of the blown air passing through the radiation fins 46 increases as well. Accordingly, the water W (residual water) inside the non-waterproof area S2 evaporates when it comes into contact with the blown air having a high temperature and, further, is discharged to the outside of the housing 12 from the second air outlet 15A by the blown air. As described above, in the tablet terminal 10, since the temperature of the blown air is increased with the increase in temperature of the radiation fins 46 that is associated with the heat generation of the CPU 27, discharge of water W from the non-waterproof area S2 of the housing 12 may be facilitated.

Furthermore, in the tablet terminal 10, since the radiation fins 46 are heated, water (not shown) that has adhered to the radiation fins 46 is evaporated and, further, is moved to the second air outlet 15A with the blown air. With the above, water may be restrained from remaining on the radiation fins 46; accordingly, even if the radiation fins 46 include copper or aluminum, corrosion of the radiation fins 46 may be averted. Furthermore, since water may be suppressed from remaining on the radiation fins 46, adhesion of dust to the radiation fins 46 may be suppressed as well.

Furthermore, in the tablet terminal 10, since the moving image program is executed automatically based on the detection result of the humidity detected by the humidity sensor 70, discharge of water W from the non-waterproof area S2 of the housing 12 may be facilitated without the user operating the tablet terminal 10.

Additionally, in the tablet terminal 10, since the radiation fins 46 are heated using the generated heat (waste heat) of the CPU 27 (see FIG. 1) provided in the waterproof area S1 (see FIG. 1), a separate component for heating the radiation fins 46 does not have to be provided. Accordingly, a reduction in size of the housing 12 may be achieved and it is possible for the tablet terminal 10 to save energy. Moreover, the number of parts used in the tablet terminal 10 may be reduced.

Furthermore, in the tablet terminal 10, since the heat pipe 29 is in contact with the undersurface of the radiation fins 46, blockage of the ascending flow of vapor from the radiation fins 46 by the heat pipe 29 may be suppressed.

Moreover, in the tablet terminal 10, since the second air outlet 15A is formed in the bottom wall 15, water W inside the non-waterproof area S2 moves towards the second air outlet 15A by its own weight. Accordingly, discharge of water W from the non-waterproof area S2 may be facilitated. Additionally, in the tablet terminal 10, since the bottom wall 15 is inclined towards the second air outlet 15A, in other words, since the bottom wall 15 includes the inclined surface 15B, discharge of water W from the second air outlet 15A may be facilitated by the weight of the water W.

Subsequently, in the tablet terminal 10, when the discharge of water W from the non-waterproof area S2 is completed, such as when there is no more water W to be discharged from the second air outlet 15A, the user attaches the cover member 60 to the second air outlet 15A. At this time, since the guided surface 62 of the cover member 60 is guided along the lateral surface of the guide wall 66, the cover member 60 may be readily attached to the second air outlet 15A. Note that when the cover member 60 is attached to the second air outlet 15A, the wire member 68 is released from the pulled state; accordingly, the end portion of the first duct member 40 moves towards the lower side.

Subsequently, the user operates the touch panel (not shown) and stops the moving image program. Then, the user slides the lever member 59 (see FIG. 3) towards the upper side. Accordingly, the second duct member 50 is moved to the open position and the first air outlet 21 is opened.

### Second Embodiment

A second embodiment of the embodiments discussed herein will be described next.

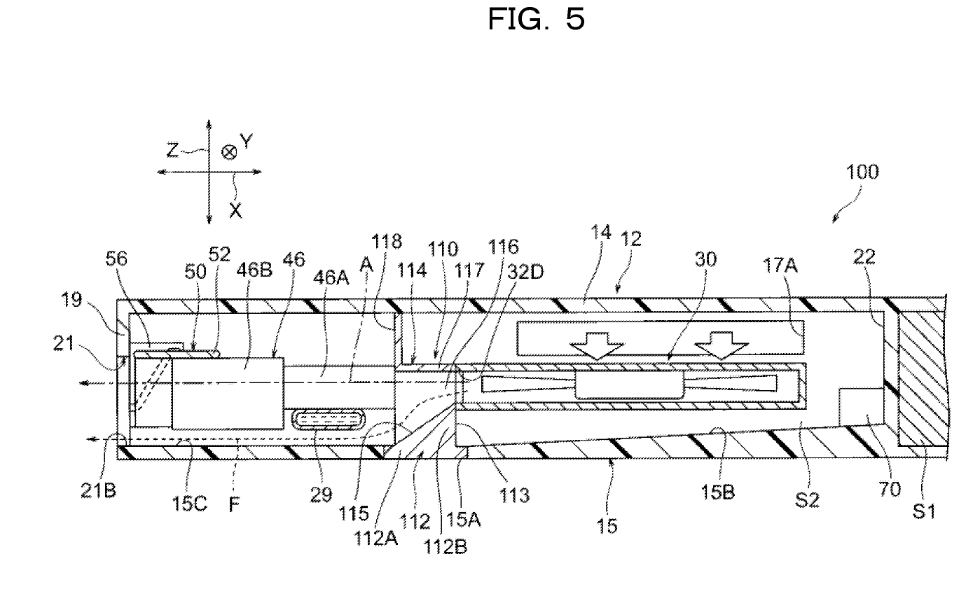

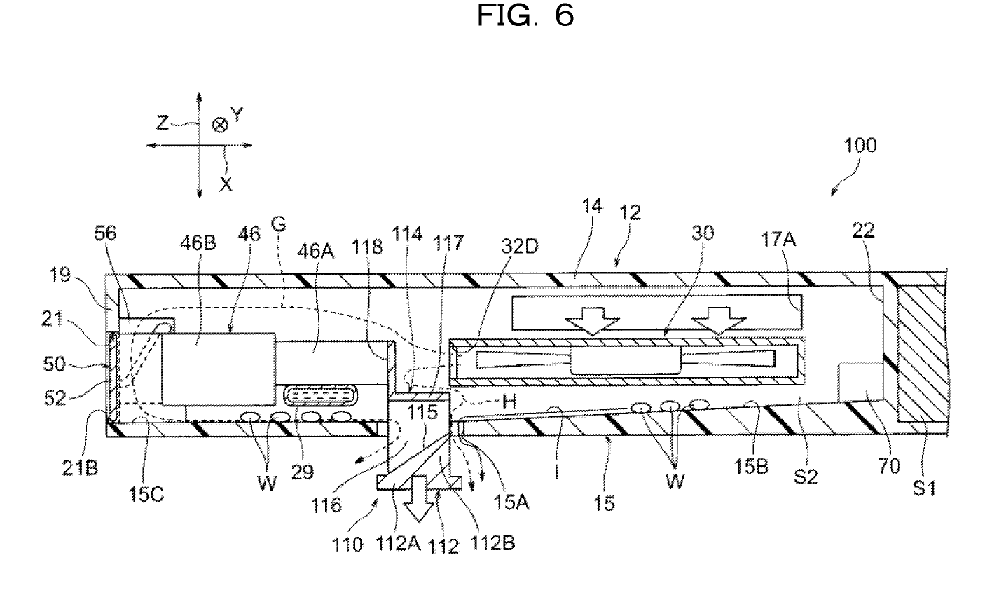

A configuration of a tablet terminal 100 serving as an example of an electronic device according to a second embodiment illustrated in FIGS. 5 and 6 is changed in the following manner with respect to the tablet terminal 10 (see FIGS. 1 to 4) according to the first embodiment described above. Note that in the second embodiment, configurations similar to those of the first embodiment described above are denoted with the same reference numerals as the first embodiment and descriptions thereof are omitted.

As illustrated in FIG. 5, the tablet terminal 100 according to the second embodiment is provided with a cut-off cover 110 in place of the cover member 60 (see FIG. 2) of the tablet terminal 10 (see FIG. 2) of the first embodiment.

The cut-off cover 110 has an integrated shape formed of a cover portion 112 serving as an example of a cover member and a guide portion 114 serving as an example of the guide member. Furthermore, the cut-off cover 110 may be moved in the Z direction between the fan unit 30 and the radiation fins 46. Note that the tablet terminal 100 has a configuration similar to that of the tablet terminal 10 (see FIG. 2) of the first embodiment except for the cut-off cover 110.

When seen from the Y direction, the cover portion 112 has a sectional shape formed of a rectangular bottom portion 112A and an inclined portion 112B, which is disposed on the upper side of the bottom portion 112A and that has a right angled triangle shape, integrated together. The bottom portion 112A has a size that fits in the second air outlet 15A. The inclined portion 112B includes a lateral surface 113 extending erect along the YZ plane and an inclined surface 115 that is inclined downwards from the upper end of the lateral surface 113 towards the other end of the bottom portion 112A in the X direction. In other words, the upper surface of the cover portion 112 and the undersurface of the guide portion 114 are the inclined surface 115 that is inclined with respect to the horizontal direction (as an example, the X direction) of the housing 12.

In a state in which the cover portion 112 closes the second air outlet 15A, the guide portion 114 is disposed between the fan unit 30 and the radiation fins 46. Furthermore, the guide portion 114 includes the inclined surface 115 serving as a bottom plate, two sidewalls 116 each standing erect in the Z direction on the front side and the rear side of the inclined surface 115 in the Y direction spaced apart from each other, and a top plate 117 that connects the upper side of the two sidewalls 116. In other words, the guide portion 114 is formed in a tube shape that extends in the X direction.

Furthermore, in the guide portion 114, the area of the opening that is on the side adjacent to the radiation fins 46 is larger than the opening area of the opening adjacent to the fan unit 30. Additionally, in the guide portion 114, the size of the opening on the side adjacent to the radiation fins 46 is larger than the external shape of the radiation fins 46.

In a state in which the cover portion 112 closes the second air outlet 15A, one end of the top plate 117 in the X direction is disposed adjacent to the top plate 32A of the fan cover 32 and the other end of the top plate 117 in the X direction is disposed adjacent to the first radiation portion 46A of the radiation fins 46. Furthermore, a plate-shaped erect portion 118 that stands erect towards the upper wall 14 of the housing 12 is formed at the end of the top plate 117 that is on the side adjacent to the radiation fins 46.

The height of the erect portion 118 in the Z direction is, for example, higher than the height of the first radiation portion 46A in the Z direction. Furthermore, in a state in which the cover portion 112 closes the second air outlet 15A, the erect portion 118 is in contact with the undersurface of the upper wall 14. Note that a stopper (not shown) that restricts the cut-off cover 110 to move towards the lower side when the erect portion 118 faces the first radiation portion 46A of the radiation fins 46 is provided in the housing 12. Furthermore, the top plate 117 and the erect portion 118 of the cut-off cover 110 are configured to remain inside the housing 12.

Functions and effects of the second embodiment will be described next.

During Normal Operation

As illustrated in FIG. 5, during normal operation of the tablet terminal 100, the first air outlet 21 is open, and the second air outlet 15A is closed by the cut-off cover 110. In other words, the second air outlet 15A, being closed by the cut-off cover 110, may suppress the blown air from leaking therefrom.

Next, when the fan unit 30 starts operating, air is blown out from the blowing port 32D. At this time, the top plate 117 covers a portion between the fan unit 30 and the radiation fins 46. Accordingly, a portion of the air blown out from the fan unit 30 flows towards the radiation fins 46 along the top plate 117 and the remaining portion flows along the inclined surface 115 to the portion below the radiation fins 46.

The portion of the air blown out from the fan unit 30 flows through the radiation fins 46 and reduces the temperature of the radiation fins 46. At this time, since the top plate 52 of the second duct member 50 covers the portion from the radiation fins 46 to the left wall 19, as illustrated by the arrow A, the air that has flowed through the radiation fins 46 flows towards the first air outlet 21, passes through the first air outlet 21, and flows to the outside of the housing 12.

Meanwhile, as illustrated by an arrow F (a broken line), the remaining air blown out from the fan unit 30 flows towards the first air outlet 21 between the radiation fins 46 and the heat pipe 29, and the bottom wall 15 (the lower portion of the housing 12), passes through the first air outlet 21, and flows to the outside of the housing 12. Accordingly, when there are water droplets due to dew condensation and the like at the lower portion of the housing 12, the water droplets are discharged to the outside of the housing 12 by the blown air illustrated by the arrow F.

During Discharge Operation

When the user slides the lever member 59 (see FIG. 3) with his/her finger towards the lower side in a case in which water W has infiltrated into the non-waterproof area S2 of the tablet terminal 100, as illustrated in FIG. 6, the first air outlet 21 is closed by the top plate 52 of the second duct member 50.

Furthermore, when the user pulls the cut-off cover 110 towards the lower side in the Z direction until the displacement of the cut-off cover 110 is restricted by the stopper described above (not shown), the erect portion 118 is disposed so as to face the blowing port 32D and a gap is formed between the top plate 117 and the fan unit 30. Accordingly, the second air outlet 15A is opened.

The blown air flowing in the X direction from the blowing port 32D of the fan unit 30 is guided by the erect portion 118 and, as illustrated by an arrow G (a broken line), flows towards the upper side, passes above the radiation fins 46, and flows to the first air outlet 21. Here, since the first air outlet 21 is closed, the blown air flows along the top plate 52 towards the lower side. Then, the blown air flows between the bottom wall 15 and the radiation fins 46, passes through the second air outlet 15A, and flows to the outside of the housing 12. Accordingly, the water W that has accumulated on the flat surface 15C of the bottom wall 15 is swept by the blown air, passes through the second air outlet 15A, and is discharged to the outside of the housing 12.

Note that, in the tablet terminal 100, since the blown air is guided to the upper portion of the housing 12 by the erect portion 118, the water droplets (not shown) that are adhered to the undersurface of the upper wall 14 may be discharged from the second air outlet 15A. Furthermore, in the tablet terminal 100, there are cases in which water W adheres to the upper portion of the cut-off cover 110 when the water W that has reached the second air outlet 15A is discharged to the outside of the housing 12. Now, since the inclined surface 115 is formed in the cut-off cover 110, the water W that has adhered to the cut-off cover 110 flows obliquely downwards on the inclined surface 115. Accordingly, water W may be suppressed from remaining on the cut-off cover 110.

As illustrated by an arrow H (a broken line), the blown air guided along the erect portion 118 and the top plate 117 towards the lower side passes through the second air outlet 15A and is discharged to the outside of the housing 12. Furthermore, as illustrated by an arrow I (a solid line), the water W on the inclined surface 15B of the bottom wall 15 flows obliquely downwards on the inclined surface 15B by its own weight and is discharged from the second air outlet 15A.

As above, in the tablet terminal 100, since the first air outlet 21 is closed by the second duct member 50, it will be possible to suppress water W from spouting out from the first air outlet 21 due to the air blown out from the fan unit 30. Furthermore, in the tablet terminal 100, discharge of water W from portions of the housing 12 unintended by the user may be restricted since the water W is discharged from the second air outlet 15A when the user detaches the cut-off cover 110. Note that even if the user changes (tilts) the position of the tablet terminal 100, discharge of water W from portions unintended by the user may be restricted since the water W is discharged from the second air outlet 15A.

Furthermore, in the tablet terminal 100, the CPU 27 (see FIG. 1) executes the moving image program when water W infiltrates into the non-waterproof area S2 and when the humidity sensor 70 detects a humidity that is equivalent to or higher than the preset humidity. Accordingly, operational load is imposed on the CPU 27 and the temperature of the CPU 27 becomes higher than the temperature of the CPU 27 when the tablet terminal 100 is booted up. Then, the heat of the CPU 27 is transmitted to the radiation fins 46 through the heat pipe 29 and the temperature of the radiation fins 46 increases.

Subsequently, with the increase in temperature of the radiation fins 46, the temperature of the blown air passing through the radiation fins 46 increases as well. Accordingly, the water W (residual water) inside the non-waterproof area S2 evaporates when it comes into contact with the blown air having a high temperature and, further, is discharged to the outside of the housing 12 from the second air outlet 15A by the blown air. As described above, in the tablet terminal 100, since the temperature of the blown air is increased with the increase in temperature of the radiation fins 46 that is associated with the heat generation of the CPU 27, discharge of water W from the non-waterproof area S2 of the housing 12 may be facilitated.

Subsequently, in the tablet terminal 100, when the discharge of water W from the non-waterproof area S2 is completed, such as when there is no more water W to be discharged from the second air outlet 15A, as illustrated in FIG. 5, the user attaches (fits) the cut-off cover 110 to the second air outlet 15A.

Subsequently, the user operates the touch panel (not shown) and stops the moving image program. Then, the user slides the lever member 59 (see FIG. 3) towards the upper side. Accordingly, the second duct member 50 is moved to the open position and the first air outlet 21 is opened.

### Third Embodiment

A third embodiment of the embodiments discussed herein will be described next.

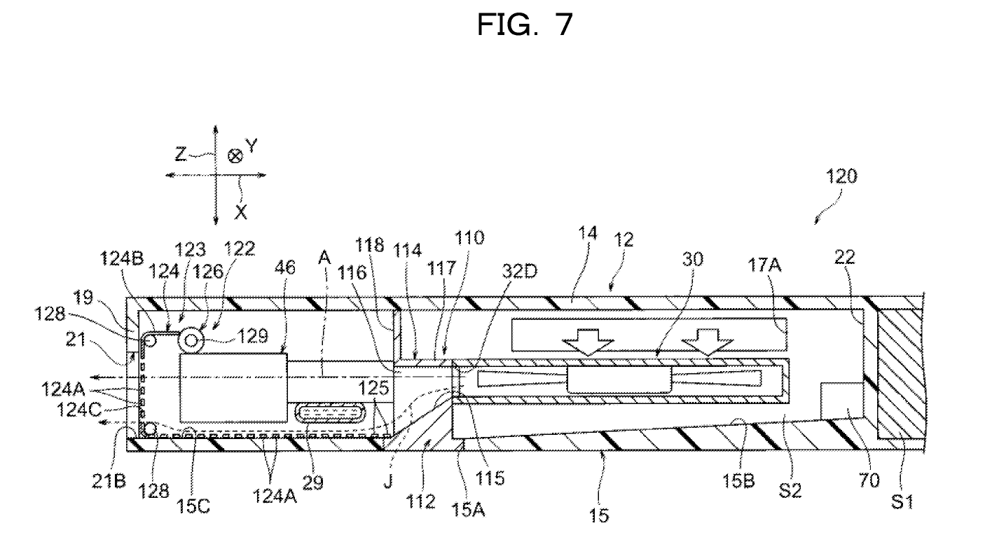

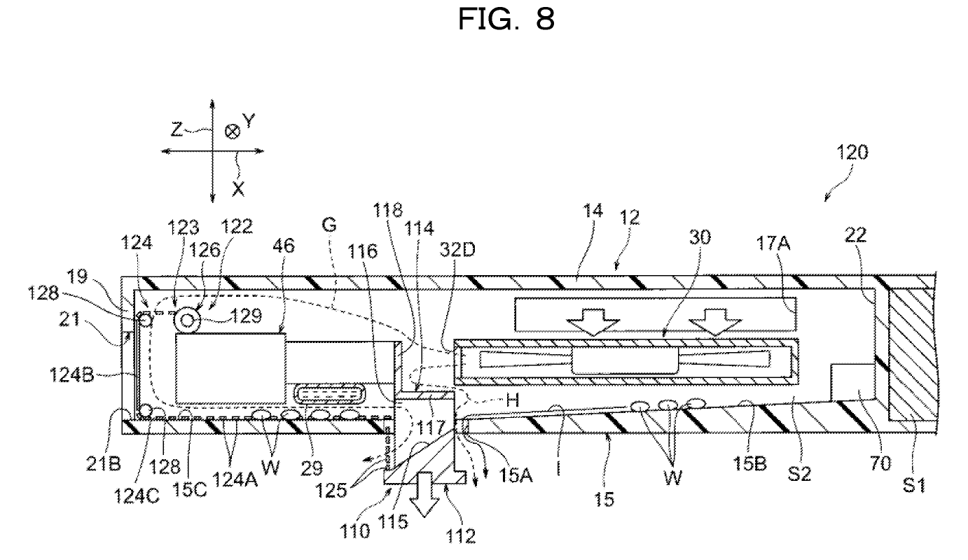

A configuration of a tablet terminal 120 serving as an example of an electronic device according to a third embodiment illustrated in FIGS. 7 and 8 is changed in the following manner with respect to the tablet terminal 100 (see FIGS. 5 and 6) according to the second embodiment described above. Note that in the third embodiment, configurations similar to those of the first and second embodiments described above are denoted with the same reference numerals as the first and second embodiments and descriptions thereof are omitted.

As illustrated in FIG. 7, the tablet terminal 120 according to the third embodiment is provided with a roller blind 122 in place of the second duct member 50 (see FIG. 5) of the tablet terminal 100 (see FIG. 5) of the second embodiment. The roller blind 122 includes, for example, a screen material 123, a winding portion 126 that winds the screen material 123 and that allows the screen material 123 to be pulled out, and two shafts 128 around which the screen material 123 are wound.

The screen material 123 is, for example, a wide film material whose width in the Y direction is wider than the width of the first air outlet 21 in the Y direction. Furthermore, the screen material 123 includes a moving portion 124 serving as an example of the opening and closing member and a connection portion 125 serving as an example of the connection member. Moreover, a portion of the moving portion 124 of the screen material 123 is wound around a rotating shaft 129 of the winding portion 126 and the connection portion 125 of the screen material 123 is connected to the cover portion 112 of the cut-off cover 110.

The moving portion 124 includes a ventilation portion 124A and a non-ventilation portion 124B. A plurality of through holes 124C is formed in the ventilation portion 124A. Note that no through holes are formed in the non-ventilation portion 124B. The connection portion 125 is, for example, formed continuously with the ventilation portion 124A.

The winding portion 126 is disposed above one end portion of the radiation fins 46 in the X direction such that the longitudinal direction of the winding portion 126 extends in the Y direction. Furthermore, the winding portion 126 includes the rotating shaft 129, two end portions of which are supported by bearing members (not shown) in a rotatable manner and in which the axial direction extends in the Y direction. As described above, the one end of the screen material 123 is fixed to the rotating shaft 129 with an adhesive. The rotating shaft 129 rotates clockwise in FIGS. 7 and 8 to wind the screen material 123 around the rotating shaft 129.

When the screen material 123 is pulled out from the winding portion 126, the rotating shaft 129 rotates counterclockwise in FIGS. 7 and 8. Note that the winding portion 126 includes a lock mechanism (not shown) so as to, during normal operation, keep the ventilation portion 124A oriented so as to face the first air outlet 21 in the X direction and so as to, during the discharge operation, keep the non-ventilation portion 124B oriented so as to face the first air outlet 21 in the X direction.

The two shafts 128 are disposed so as to be spaced apart from the inner surface of the left wall 19 and are disposed so as to be spaced apart from each other in the Z direction. Furthermore, the axial direction of each of the two shafts 128 extends in the Y direction, and when viewed in the X direction, the two shafts 128 are disposed so that the first air outlet 21 is positioned therebetween. Moreover, by winding the screen material 123 around each of the two shafts 128, the screen material 123 between the two shafts 128 is extended along the YZ plane and is positioned so as to face the first air outlet 21.

As above, in the tablet terminal 120, when the cut-off cover 110 closes the second air outlet 15A, the ventilation portion 124A is arranged so as to face the first air outlet 21. Furthermore, in the tablet terminal 120, when the cut-off cover 110 opens the second air outlet 15A, the non-ventilation portion 124B is arranged so as to face the first air outlet 21.

Functions and effects of the third embodiment will be described next.

During Normal Operation

As illustrated in FIG. 7, during normal operation, ventilation is allowed in the first air outlet 21 through the through holes 124C and the second air outlet 15A is closed by the cut-off cover 110.

Subsequently, when the fan unit 30 starts operating, as illustrated by the arrow A, the blown air that has flowed through the radiation fins 46 flows towards the first air outlet 21, passes through the through holes 124C and the first air outlet 21, and flows to the outside of the housing 12.

Meanwhile, as illustrated by an arrow J (a broken line), the remaining air blown out from the fan unit 30 flows towards the first air outlet 21 between the radiation fins 46 and the heat pipe 29, and the bottom wall 15, passes through the through holes 124C and the first air outlet 21, and flows to the outside of the housing 12. Accordingly, when there are water droplets due to dew condensation and the like at the lower portion of the housing 12, the water droplets are discharged to the outside of the housing 12 by the blown air illustrated by an arrow L.

During Discharge Operation

As illustrated in FIG. 8, when water W infiltrates into the non-waterproof area S2 of the tablet terminal 120, the user pulls the cut-off cover 110 towards the lower side in the Z direction until the displacement of the cut-off cover 110 is restricted by the stopper (not shown) described above. Accordingly, the erect portion 118 is disposed so as to face the blowing port 32D and a gap is formed between the top plate 117 and the fan unit 30. Furthermore, the second air outlet 15A becomes open. At this time, while the cut-off cover 110 is displaced to the lower side, the screen material 123 is pulled out from the winding portion 126. Then, when the displacement of the cut-off cover 110 is restricted, the non-ventilation portion 124B is disposed so as to face the first air outlet 21 such that the first air outlet 21 is covered.

Next, as illustrated by the arrow G, the blown air flowing in the X direction from the blowing port 32D of the fan unit 30 passes above the radiation fins 46 and flows to the first air outlet 21. Here, since the first air outlet 21 is closed by the non-ventilation portion 124B, the blown air flows along the screen material 123 towards the lower side. Then, the blown air flows between the bottom wall 15 and the radiation fins 46, passes through the second air outlet 15A, and flows to the outside of the housing 12. Accordingly, the water W that has accumulated on the flat surface 15C of the bottom wall 15 is swept by the blown air, passes through the second air outlet 15A, and is discharged to the outside of the housing 12.

Note that, in the tablet terminal 120, since the blown air is guided to the upper portion of the housing 12 by the erect portion 118, the water droplets (not shown) that are adhered to the undersurface of the upper wall 14 may be discharged from the second air outlet 15A.

Meanwhile, as illustrated by the arrow H, the blown air guided along the erect portion 118 and the top plate 117 towards the lower side passes through the second air outlet 15A and is discharged to the outside of the housing 12. Furthermore, as illustrated by the arrow I, the water W on the inclined surface 15B of the bottom wall 15 flows obliquely downwards on the inclined surface 15B by its own weight and is discharged from the second air outlet 15A.

As above, in the tablet terminal 120, since the first air outlet 21 is closed by the screen material 123, it will be possible to suppress water W from spouting out from the first air outlet 21 due to the air blown out from the fan unit 30. Furthermore, in the tablet terminal 120, discharge of water W from portions of the housing 12 unintended by the user may be restricted since the water W is discharged from the second air outlet 15A when the user detaches the cut-off cover 110. Note that even if the user changes (tilts) the position of the tablet terminal 120, discharge of water W from portions unintended by the user may be restricted since the water W is discharged from the second air outlet 15A.

Furthermore, in the tablet terminal 120, the CPU 27 (see FIG. 1) executes the moving image program when water W infiltrates into the non-waterproof area S2 and when the humidity sensor 70 detects a humidity that is equivalent to or higher than the preset humidity. Then, the heat of the CPU 27 is transmitted to the radiation fins 46 through the heat pipe 29 and the temperature of the radiation fins 46 increases.

Subsequently, with the increase in temperature of the radiation fins 46, the temperature of the blown air passing through the radiation fins 46 increases as well. Accordingly, the water W (residual water) inside the non-waterproof area S2 evaporates when it comes into contact with the blown air having a high temperature and, further, is discharged to the outside of the housing 12 from the second air outlet 15A by the blown air. As described above, in the tablet terminal 120, since the temperature of the blown air is increased with the increase in temperature of the radiation fins 46 that is associated with the heat generation of the CPU 27, discharge of water W from the non-waterproof area S2 of the housing 12 may be facilitated.

Subsequently, in the tablet terminal 120, when the discharge of water W from the non-waterproof area S2 is completed, such as when there is no more water W to be discharged from the second air outlet 15A, as illustrated in FIG. 7, the user attaches the cut-off cover 110 to the second air outlet 15A. At this time, the screen material 123 is wound by the winding portion 126 such that the ventilation portion 124A is disposed so as to face the first air outlet 21. Subsequently, the user operates the touch panel (not shown) and stops the moving image program.

As described above, in the tablet terminal 120, since the screen material 123 is connected to the cut-off cover 110, the second air outlet 15A may be opened and the screen material 123 may be displaced by a single operation of moving the cut-off cover 110 towards the lower side.

Furthermore, in the tablet terminal 120, since it is only sufficient to connect the screen material 123 that forms the ventilation portion 124A and the non-ventilation portion 124B to the cut-off cover 110, opening and closing of the first air outlet 21 may be carried out with a simple configuration.

Modifications of the embodiments will be described next. In the first, second, and third embodiments described above, the tablet terminals have been described as examples of the electronic device; however, the electronic device may be any other electronic device such as a notebook type personal computer, a smart phone (registered trademark), or the like.

The tablet terminals 10, 100, and 120 are not limited to ones having a non-waterproof area S2 disposed on the left rear portion in plan view as long as the non-waterproof area S2 is arranged adjacent to the sidewall 13. Furthermore, the tablet terminals 10, 100, and 120 may be ones without any humidity sensor 70. In such a case, during the discharge operation, the user may operate the touch panel (not shown) and activate the moving image program.

The fan unit 30 is not limited to a sirocco fan and may be an axial fan or a cross flow fan. As regards the radiation fins 46, the first radiation portion 46A and the second radiation portion 46B may be integrated. As regards the fin shape, the fin material, and the position where the heat pipe 29 is in contact with the fin are not limited to those of the radiation fins 46.

The position where the second air outlet 15A is formed is not limited to the bottom wall 15 and may be a lower portion of the sidewall 13. Note that the liquid is not limited to water and may be a liquid other than water or may be water mixed with other components.

The first duct member 40 is not limited to one that is connected to the cover member 60 with the wire member 68. For example, the first duct member 40 may be connected to the cover member 60 using a link mechanism. Furthermore, the first duct member 40 is not limited to one with a tube shape; the first duct member 40 may be one with a C-shaped section or one with a section having another shape.

The opening and closing member is not limited to one that forms a duct such as the second duct member 50 and may be, for example, a shutter member that moves in the up-down direction to open and close the first air outlet 21. Furthermore, the second duct member 50 may have no sidewalls 54.

Note that the components used in the first, second, and third embodiment described above may be combined and implemented as appropriate.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a fan;
a housing configured to house the fan, the housing including a vent hole configured to introduce outside air, a first air outlet configured to open to a blowing path from the fan, and a second air outlet configured to open at a different position with respect to the blowing path; and
a first duct configured to open and close the first air outlet.

2. The electronic device according to claim 1, wherein
the second air outlet is provided with a cover configured to open and close the second air outlet.

3. The electronic device according to claim 2, wherein
the cover is coupled to a connector configured to perform an opening and closing operation of the first duct upon opening and closing of the cover.

4. The electronic device according to claim 3, wherein
the first duct includes an air vent and a non-air vent configured to do not vent air, and
when the cover closes the second air outlet, the ventilation portion is disposed so as to face the first air outlet, and when the cover opens the second air outlet, the non-ventilation portion is disposed so as to face the first air outlet.

5. The electronic device according to claim 2, further comprising
a first heat conductor configured to release heat of an electronic component in operation is provided between the fan and the first air outlet, and
a second duct configured to guide, to the first heat conductor, air blown out from the fan is provided between the fan and the first heat conductor, wherein
the second duct is coupled to the cover or is integrated with the cover.

6. The electronic device according to claim 5, wherein
an opening of the second duct on an outflow side is larger than an opening of the second duct on an inflow side and the second duct guides the air blown out from the fan to the first heat conductor and to an upper portion of the housing when the second air outlet is open.

7. The electronic device according to claim 5, wherein
the second duct and the second air outlet are arranged with respect to each other in a direction configured to intersect a blowing direction of the fan.

8. The electronic device according to claim 5, wherein
the second duct is supported by the cover when the second air outlet is closed.

9. The electronic device according to claim 5, wherein
an erect portion configured to stand erect towards an upper wall of the housing is formed on an upper portion of the second duct, and
the erect portion guides the air blown out from the fan towards the upper wall when the cover is moved and the second air outlet is opened.

10. The electronic device according to claim 5, wherein
an upper surface of the cover and an undersurface of the second duct are inclined surfaces that are inclined with respect to a horizontal direction of the housing.

11. The electronic device according to claim 5, further comprising
a controller configured to perform control of operating the electronic component upon reception of a liquid discharge command.

12. The electronic device according to claim 11, wherein
a sensor configured to detect a humidity inside the housing is provided in the housing, and
the controller operates the electronic component when the detected humidity is equivalent to or higher than a preset humidity.

13. The electronic device according to claim 5, wherein
the housing includes a non-waterproof area in which the first air outlet and the second air outlet are formed and in which the fan and the first duct are housed and a waterproof area that is partitioned from the non-waterproof area with a partition wall,
the first heat conductor is disposed in the non-waterproof area,
the electronic component is disposed in the waterproof area, and
a second heat conductor configured to penetrate the partition wall so as to be disposed in the waterproof area and the non-waterproof area is provided in the housing, the second heat conductor transmitting the heat of the electronic component to the first heat conductor.

14. The electronic device according to claim 13, wherein
the second heat conductor is in contact with the first heat conductor.

15. The electronic device according to claim 2, wherein
a guide wall configured to guide the cover from the second air outlet to inside the housing is provided in the housing.

16. The electronic device according to claim 1, wherein
the first air outlet is formed in a sidewall of the housing, and
the second air outlet is formed in a bottom wall of the housing.

17. The electronic device according to claim 16, wherein
the bottom wall is inclined downwards towards the second air outlet.

18. The electronic device according to claim 1, wherein
the fan and the opening and closing member are provided in the housing of a tablet terminal.
